(19) United States
(12) Patent Application Publication
(10) Pub. No.: US 2008/0062609 A1
(43) Pub. Date: Mar. 13, 2008

(54) ELECTROSTATIC CHUCK DEVICE

(76) Inventors: Shinji HIMORI, Nirasaki-shi (JP); Shoichiro MATSUYAMA, Nirasaki-shi (JP); Atsushi MATSUURA, Nirasaki-shi (JP); Hiroshi INAZUMACHI, Funabashi-shi (JP); Mamoru KOSAKAI, Narashino-shi (JP)

Correspondence Address: OSTROLENK FABER GERB & SOFFEN, 1180 AVENUE OF THE AMERICAS, NEW YORK, NY, 100368403, US

(21) Appl. No.: 11/834,957

(22) Filed: Aug. 7, 2007

Related U.S. Application Data
(60) Provisional application No. 60/828,403, filed on Oct. 6, 2006.

(30) Foreign Application Priority Data
Aug. 10, 2006 (JP) 2006-218448

(51) Int. Cl. H01L 21/683

(52) U.S. Cl. 361/234

(57) ABSTRACT

An electrostatic chuck device includes: an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and a metal base section that is fixed to the other main surface of the electrostatic chuck section so as to be incorporated into a body and that serves as a high frequency generating electrode. Here, the electrostatic-adsorption inner electrode has one or more electrode portions, and a resistance value of a distance between a point corresponding to a center axis of the substrate or a point closest to the center axis and a point most distant from the center axis among distances between two points in the electrode portion is in the range of 10²Ω to 10¹⁰Ω.

### BACKGROUND OF THE INVENTION

1. Field of the Invention

The present invention relates to an electrostatic chuck device, and more particularly, to an electrostatic chuck device suitable for use in a high-frequency discharge type plasma processing apparatus for applying a high-frequency voltage to an electrode to generate plasma and processing a plate-like sample such as a semiconductor wafer, a metal wafer, and a glass plate by the use of the generated plasma.

Priority is claimed on Japanese Application No. 2006-218448, filed Aug. 10, 2006, which is incorporated herein by reference. This application also claims the benefit pursuant to 35 U.S.C. §102(e) of U.S. Provisional Application No. 60/828,403, filed on Oct. 6, 2006.

2. Description of the Related Art

Conventionally, plasma was often used in processes such as etching, deposition, oxidation, and sputtering for manufacturing semiconductor devices such as IC, LSI, and VLSI or flat panel displays (FPD) such as a liquid crystal display, in order to allow a process gas to react well at a relatively low temperature. In general, methods of generating plasma in plasma processing apparatuses are roughly classified into a method using glow discharge or high-frequency discharge and a method using microwaves.

FIG. 11 is a cross-sectional view illustrating an example of an electrostatic chuck device 1 mounted on a known high-frequency discharge type plasma processing apparatus. The electrostatic chuck device 1 is disposed in a lower portion of a chamber (not shown) also serving as a vacuum vessel and includes an electrostatic chuck section 2 and a metal base section 3 fixed to the bottom surface of the electrostatic chuck section 2 so as to be incorporated into a body.

The electrostatic chuck section 2 includes: a substrate 4, which has a top surface serving as a mounting surface 4a, on which a plate-like sample W such as a semiconductor wafer is disposed, so as to adsorb the plate-like sample W in an electrostatic manner, and an electrostatic-adsorption inner electrode 5 built therein; and a power supply terminal 6 for applying a DC voltage to the electrostatic-adsorption inner electrode 5. A DC voltage source 7 is connected to the power supply terminal 6. The metal base section 3, which is also used as a high-frequency generating electrode (lower electrode), is connected to a high-frequency voltage generating source 8 and has a flow passage 9 for circulating a cooling medium such as water or an organic solvent formed therein. The chamber is grounded.

The electrostatic chuck device 1 adsorbs the plate-like sample W, by placing the plate-like sample W on the mounting surface 4a and allowing the DC voltage source 7 to apply a DC voltage to the electrostatic-adsorption inner electrode 5 through the power supply terminal 6. Subsequently, a vacuum is formed in the chamber and a process gas is introduced thereto. Then, by allowing the high-frequency voltage generating source 8 to apply high-frequency power across the metal base section 3 and the chamber, a high-frequency electric field is generated in the chamber. Frequencies of 27 MHz or less are generally used as the high frequency.

The high-frequency electric field accelerates electrons, plasma is generated due to ionization by collision of the electrons with the process gas, and a variety of processes can be performed by the use of the generated plasma.

Recently, with a miniaturization in design rule of manufacture processes, a high-density plasma process under a low pressure has been required as a plasma process. The above-mentioned high-frequency discharge type plasma processing apparatus used a frequency in a high frequency region of 50 MHz or more, which is much higher than that of the conventional frequency.

When the frequency of the high-frequency discharge rises and a high-frequency voltage is applied to the metal base section, current flows from the peripheral edge on the surface of the metal base section to the central portion due to a skin effect. Accordingly, the electric field strength at the center of the surface of the metal base section is higher than the electric field strength of the peripheral edge, the density of the generated plasma is higher at the center than in the peripheral edge, and thus the resistivity of the plasma is lowered at the central portion of the metal base section which has a high plasma density.

As a result, the plasma density on the surface of the metal base section becomes more non-uniform, thereby preventing a uniform plasma process on the plate-like sample.

In order to solve the above-mentioned problem, an electrostatic chuck device shown in FIG. 12 has been suggested (see Patent Literature 1).

In the electrostatic chuck device 11, a plurality of convex portions 13 are discretely formed on the surface of a disc-shaped metal plate 12 also serving as a high frequency generating electrode, an alumina (Al₂O₃)-sprayed film 14 as a dielectric material is formed on the entire surface of the metal plate 12 including the convex portion 13, an electrostatic-adsorption inner electrode 15 is built in the alumina-sprayed film 14, and the surface of the alumina-sprayed film 14 serves as a mounting surface 14a on which a plate-like sample W such as a semiconductor wafer is mounted so as to electrostatically adsorb the plate-like sample.

In the electrostatic chuck device 11, when a high-frequency voltage is applied to the metal plate 12, the alumina (Al₂O₃) buried in the concave portion between the convex portions 13 prevents current from flowing from the peripheral portion of the surface of the metal base section to the central portion thereof due to the skin effect. Accordingly, the electric field strength on the surface of the metal base section is made to be uniform and thus the plasma density is made to be even.

[Patent Literature 1] Japanese Patent Unexamined Publication No. 2004-363552

However, in the above-mentioned electrostatic chuck device 11, since the alumina (Al₂O₃) is filled in the concave portions between the convex portions 13 by the use of the thermal spraying method, the depth of the concave portions is intrinsically limited to about 1 mm. Accordingly, there is a problem in that the melted alumina (Al₂O₃) is not filled in the concave portions with a high density by the use of the thermal spraying method and it is thus not possible to effectively prevent current from flowing from the peripheral portion of the surface of the metal base section toward the central portion thereof due to the skin effect.

### SUMMARY OF THE INVENTION

The invention is made to solve the above-mentioned problems. An object of the invention is to provide an electrostatic chuck device, which can effectively prevent current from flowing from the peripheral edge of a surface of a metal base section toward the central portion thereof due to the skin effect, can suppress a plasma distribution on the surface of a plate-like sample from being disturbed, can make a plasma density even, and thus can perform a uniform plasma process on the entire surface of the plate-like sample.

As a result of keen studies for accomplishing the above-mentioned object, the inventors found that the above-mentioned problems could be efficiently solved by constructing an electrostatic-adsorption inner electrode built in a substrate with one or more electrode portions and setting a resistance value of a distance between a point corresponding to the center axis of the substrate or a point closest to the center axis and a point most distant from the center axis, among distances between two points in the electrode portion, to the range of 10²Ω to 10¹⁰Ω and thus completed the invention.

That is, according to an aspect of the invention, there is provided an electrostatic chuck device including: an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and a metal base section that is fixed to the other main surface of the substrate of the electrostatic chuck section so as to be incorporated into a body and that serves as a high frequency generating electrode. Here, the electrostatic-adsorption inner electrode has one or more electrode portions, and a resistance value of a distance between a point corresponding to a center axis of the substrate or a point closest to the center axis and a point most distant from the center axis among distances between two points in the electrode portion is in the range of 10²Ω to 10¹⁰Ω.

In the electrostatic chuck device, a high-frequency current for generating plasma is prevented from flowing from the peripheral edge of the electrostatic chuck section toward the central portion thereof through the electrostatic-adsorption inner electrode, by constructing the electrostatic-adsorption inner electrode with one or more electrode portions and setting a resistance value of a distance between a point corresponding to the center axis of the substrate or a point closest to the center axis and a point most distant from the center axis, among distances between two points in each of the one or more electrode portions, to the range of 10²Ω to 10¹⁰Ω. Accordingly, the plasma density on the surface of the plate-like sample is made to be even and thus a uniform plasma process can be performed on the entire surface of the plate-like sample.

In the electrostatic chuck device according to the invention, it is possible to prevent a high-frequency current for generating plasma from flowing from the peripheral edge of the electrostatic chuck section toward the central portion thereof through the electrostatic-adsorption inner electrode, since the electrostatic-adsorption inner electrode includes one or more electrode portions and a resistance value of a distance between a point corresponding to the center axis of the substrate or a point closest to the center axis and a point most distant from the center axis among distances between two points in each of the one or more electrode portions is set to the range of 10²Ω to 10¹⁰Ω. Accordingly, it is possible to make the plasma density on the surface of the plate-like sample even and thus to perform a uniform plasma process on the entire surface of the plate-like sample.

The action and responsiveness of the electrostatic adsorption force is excellent.

### BRIEF DESCRIPTION OF THE DRAWINGS

FIG. 1 is a sectional view illustrating an electrostatic chuck device according to a first embodiment of the invention.

FIG. 2 is a sectional view illustrating a state where an electrostatic-adsorption inner electrode according to the first embodiment of the invention is formed on a support plate of a substrate.

FIG. 3 is a sectional view illustrating a state where an electrostatic-adsorption inner electrode according to a second embodiment of the invention is formed on a support plate of a substrate.

FIG. 4 is a sectional view illustrating a state where an electrostatic-adsorption inner electrode according to a third embodiment of the invention is formed on a support plate of a substrate.

FIG. 5 is a sectional view illustrating a state where an electrostatic-adsorption inner electrode according to a fourth embodiment of the invention is formed on a support plate of a substrate.

FIG. 6 is a sectional view illustrating a state where an electrostatic-adsorption inner electrode according to a fifth embodiment of the invention is formed on a support plate of a substrate.

FIG. 7 is a sectional view illustrating a state where an electrostatic-adsorption inner electrode according to a sixth embodiment of the invention is formed on a support plate of a substrate.

FIG. 8 is a sectional view illustrating a state where an electrostatic-adsorption inner electrode according to a seventh embodiment of the invention is formed on a support plate of a substrate.

FIG. 9 is a sectional view illustrating a state where an electrostatic-adsorption inner electrode according to an eighth embodiment of the invention is formed on a support plate of a substrate.

FIG. 10 is a sectional view illustrating a state where an electrostatic-adsorption inner electrode according to a ninth embodiment of the invention is formed on a support plate of a substrate.

FIG. 11 is a sectional view illustrating an example of a known electrostatic chuck device.

FIG. 12 is a sectional view illustrating another example of a known electrostatic chuck device.

### DETAILED DESCRIPTION OF THE INVENTION

### First Embodiment

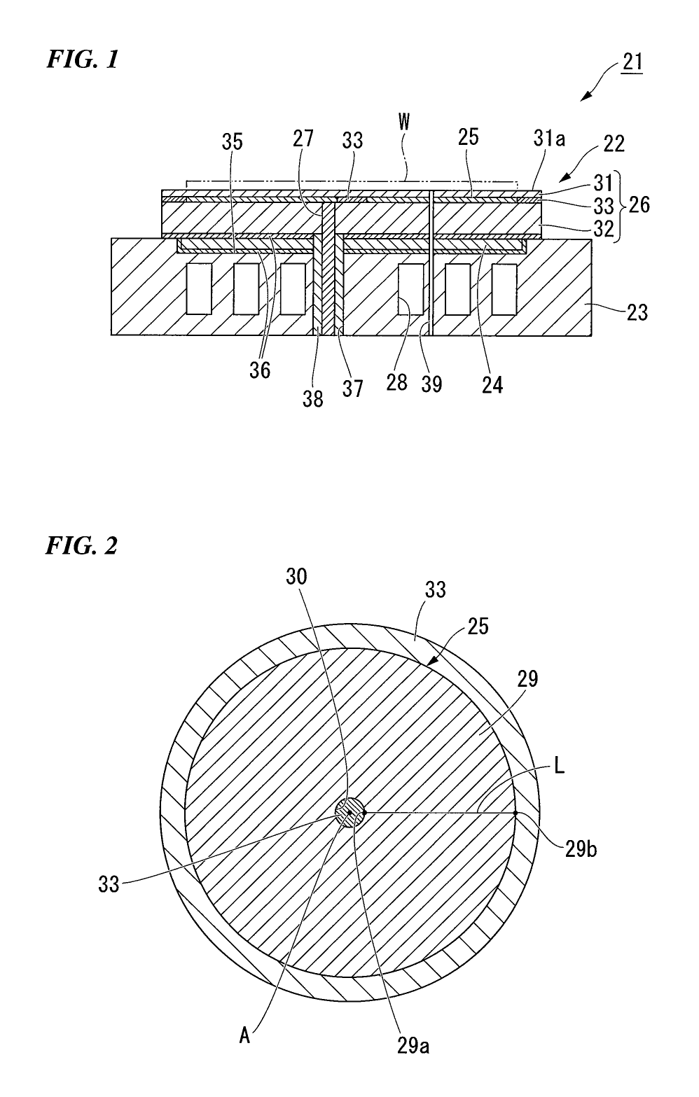

FIG. 1 is a cross-sectional view illustrating a unipolar electrostatic chuck device 21 according to a first embodiment of the invention. The electrostatic chuck device 21 includes an electrostatic chuck section 22, a metal base section 23, and a dielectric plate 24.

The electrostatic chuck section 22 includes a disc-like substrate 26, the top surface (one main surface) of which serves as a mounting surface for mounting a plate-like sample W and in which an electrostatic-adsorption inner electrode 25 is built, and a power supply terminal 27 for applying a DC voltage to the electrostatic-adsorption inner electrode 25.

The substrate 26 roughly includes a disc-like mounting plate 31 of which the top surface 31a (one main surface) serves as the mounting surface for mounting a plate-like sample W such as a semiconductor wafer, a metal wafer, and a glass plate, a disc-like support plate 32 disposed opposite the bottom surface (the other main surface) of the mounting plate 31, and an electrostatic-adsorption inner electrode 25 interposed between the mounting plate 31 and the support plate 32.

An insulating layer 33 is formed in circular openings at the central position and at the outside peripheral position of the electrostatic-adsorption inner electrode 25.

FIG. 2 is a sectional view illustrating a state where the electrostatic-adsorption inner electrode 25 is formed on the support plate 32 of the substrate 26. The electrostatic-adsorption inner electrode 25 includes one electrode portion 29 in which a circular opening 30 is formed at the central position of a disc-shaped electrode portion and a resistance value of the shortest distance L between a point 29a closest to the center axis A of the substrate 26 and a point most distant from the center axis A, that is, a point 29b closest to the peripheral edge of the substrate 26, among distances between two points in the electrode portion 29 is set to the range of 10²Ω to 10¹⁰Ω.

On the other hand, a flow passage 28 for circulating a cooling medium such as water or an organic solvent is formed in the metal base section 23 so as to maintain the plate-like sample W mounted on the mounting surface at a desired temperature. The metal base section 23 is also used as a high frequency generating electrode.

A circular concave portion 35 is formed in the surface (main surface) of the metal base section 23 facing the electrostatic chuck section 22 and the dielectric plate 24 is adhesively bonded and fixed to the concave portion 35 with an insulating adhesive bonding layer 36 interposed therebetween. The dielectric plate 24 and the support plate 32 of the electrostatic chuck section 22 are adhesively bonded to each other with an insulating adhesive bonding layer 36 interposed therebetween.

A power supply terminal insertion hole 37 is formed in the vicinity at the center of the support plate 32 and the metal base section 23 and a power supply terminal 27 for applying a DC voltage to the electrostatic-adsorption inner electrode 25 is inserted into the power supply terminal insertion hole 37 with a cylindrical insulator 38 interposed therebetween. The top end of the power supply terminal 27 is electrically connected to the electrostatic-adsorption inner electrode 25.

A cooling gas introduction hole 39 penetrating the mounting plate 31, the support plate 32, the dielectric plate 24, the electrostatic-adsorption inner electrode 25, and the metal base section 23 is formed therein and thus a cooling gas such as He is supplied to a gap between the mounting plate 31 and the bottom surface of the plate-like sample W through the cooling gas introduction hole 39.

The top surface 31a of the mounting plate 31 serves as an electrostatic adsorption surface which is mounted with a sheet of the plate-like sample W so as to electrostatically adsorb the plate-like sample W by means of an electrostatic adsorption force. The top surface (electrostatic adsorption surface) 31a is provided with a plurality of cylindrical protrusions (not shown) having a substantially circular section along the top surface 31a and the top surfaces of the protrusions are parallel to the top surface 31a.

A wall portion (not shown) that continuously extends along the peripheral portion and that has the same height as the protrusions so as not to leak the cooling gas such as He is formed in the peripheral portion of the top surface 31a so as to surround the peripheral portion of the top surface 31a circularly.

The electrostatic chuck device 21 having the above-mentioned configuration is placed in a chamber of a plasma processing apparatus such as a plasma etching apparatus, a plate-like sample W is mounted on the top surface 31a as the mounting surface, and then a variety of plasma processes can be performed on the plate-like sample W by applying a high-frequency voltage across the metal base section 23 also serving as a high frequency generating electrode and the chamber to generate plasma on the mounting plate 31 while applying a predetermined DC voltage to the electrostatic-adsorption inner electrode 25 through the power supply terminal 27 to adsorb and fix the plate-like sample W by the use of an electrostatic force.

Next, the elements of the electrostatic chuck device will be described in more detail.

“Mounting Plate and Support Plate”

The mounting plate 31 and the support plate 32 are both made of ceramics.

Ceramics including one kind selected from or complex ceramics including two or more kinds selected from aluminum nitride (AlN), aluminum oxide (Al₂O₃), silicon nitride (Si₃N₄), zirconium oxide (ZrO₂), sialon, boron nitride (BN), and silicon carbide (SiC) can be preferably used as the ceramics.

The materials may be used alone or in combination. It is preferable that the thermal expansion coefficient thereof be as close as possible to that of the electrostatic-adsorption inner electrode 25 and that they can be easily sintered. Since the top surface 31a of the mounting plate 31 serves as an electrostatic adsorption surface, it is preferable that a material having a high dielectric constant and not providing as impurities for the plate-like sample W be selected.

In consideration of the above description, the mounting plate 31 and the support plate 32 are made of a silicon carbide-aluminum oxide complex sintered body in which silicon carbide is contained substantially in the range of 1 wt % to 20 wt % and the balance is aluminum oxide.

When a complex sintered body including aluminum oxide (Al₂O₃) and silicon carbide (SiC) of which the surface is coated with silicon oxide (SiO₂) is used as the silicon carbide-aluminum oxide complex sintered body and the content of silicon carbide (SiC) is set to the range of 5 wt % to 15 wt % with respect to the entire complex sintered body, the volume resistivity at room temperature (25° C.) is 1.0×10¹⁴Ω cm or more and thus the complex sintered body is suitable for the mounting plate 31 of a coulomb type electrostatic chuck device. The complex sintered body is excellent in wear resistance, does not cause contamination of a wafer or generation of particles, and has enhanced plasma resistance.

When a complex sintered body including aluminum oxide (Al₂O₃) and silicon carbide (SiC) is used as the silicon carbide-aluminum oxide complex sintered body and the content of silicon carbide (SiC) is set to the range of 5 wt % to 15 wt % with respect to the entire complex sintered body, the volume resistivity thereof at room temperature (25° C.) is in the range of 1.0×10⁹Ωcm to 1.0×10¹²Ωcm, and thus the complex sintered body is suitable for the mounting plate 31 of a Johnson-Rahbeck type electrostatic chuck device. The complex sintered body is excellent in wear resistance, does not cause contamination of a wafer or generation of particles, and has enhanced plasma resistance.

The average particle diameter of silicon carbide particles in the silicon carbide-aluminum oxide complex sintered body is preferably 0.2 μm or less.

When the average particle diameter of the silicon carbide particles is greater than 0.2 μm, the electric field at the time of application of the plasma is concentrated on portions of the silicon carbide particles in the silicon carbide-aluminum oxide complex sintered body, thereby easily damaging the peripheries of the silicon carbide particles.

The average particle diameter of the aluminum oxide particles in the silicon carbide-aluminum oxide complex sintered body is preferably 2 μm or less.

When the average particle diameter of the aluminum oxide particles is greater than 2 μm, the silicon carbide-aluminum oxide complex sintered body is easily etched by the plasma to form sputtering scars, thereby increasing the surface roughness.

“Electrostatic-Adsorption Inner Electrode”

In the electrostatic-adsorption inner electrode 25, a circular opening 30 is formed at the center of an electrode portion 29 made of disc-shaped ceramics with a thickness in the range of about 10 μm to 50 μm. The shape or size of the electrode portion 29 is suitably adjusted depending on the shape or size of the plate-like sample W to be mounted. Among distances between two points in the electrode portion 29, a resistance value of the shortest distance L between a point 29a closest to the center axis A of the substrate 26 and a point most distant from the center axis A, that is, a point 29b closest to the peripheral edge of the substrate 26, is preferably in the range of 10²Ω to 10¹⁰Ω, more preferably in the range of 10²Ω to 10⁸Ω, and still more preferably in the range of 10³Ω to 10⁶Ω.

Here, the reason for limiting the resistance value of the shortest distance L to the above-mentioned range is as follows. When the resistance value of the shortest distance L is less than 10²Ω, a high-frequency current for generating plasma flows from the peripheral portion of the electrostatic chuck section 22 toward the central portion through the electrostatic-adsorption inner electrode 25, thereby not obtaining the uniform plasma. On the other hand, when the resistance value of the shortest distance L is greater than 10¹⁰Ω, the electrostatic-adsorption inner electrode 25 substantially becomes an insulator and thus does not function as an electrostatic-adsorption inner electrode so as not to generate an electrostatic adsorption force, or the responsiveness of the electrostatic adsorption force is deteriorated and thus a long time is required for generating the necessary electrostatic adsorption force.

Conductive ceramics having a thermal expansion coefficient similar to the thermal expansion coefficients of the mounting plate 31 and the support plate 32 can be preferably used for the ceramics constituting the electrostatic-adsorption inner electrode 25, and examples thereof include the following various complex sintered bodies:

(1) a complex sintered body in which semiconductor ceramics such as silicon carbide (SiC) are added to the insulating ceramics such as aluminum oxide;

(2) a complex sintered body in which conductive ceramics such as tantalum nitride (TaN), tantalum carbide (TaC), and molybdenum carbide (Mo₂C) are added to the insulating ceramics such as aluminum oxide; and

(3) a complex sintered body in which high melting-point metal such as molybdenum (Mo), tungsten (W), and tantalum (Ta) is added to the insulating ceramics such as aluminum oxide.

“Insulating Layer”

The insulating layer 33 serves to bond the mounting plate 31 and the support plate 32 to each other to form a body and to protect the electrostatic-adsorption inner electrode 25 from plasma or corrosive gas. A high-resistance material having the same main component as the mounting plate 31 and the support plate 32 and having a resistance value greater than that of the material of the electrostatic-adsorption inner electrode 25 can be preferably used as the material of the insulating layer 33 and an insulator is more preferably used.

For example, when the mounting plate 31, the support plate 32, and the electrostatic-adsorption inner electrode 25 are formed of the silicon carbide-aluminum oxide complex sintered body, it is preferable that the insulating layer be made of a silicon carbide-aluminum oxide complex sintered body having a content of silicon carbide lower than that of the complex sintered body, or the aluminum oxide (Al₂O₃).

“Dielectric Plate”

The dielectric plate 24 serves to prevent a current from flowing from the peripheral edge toward the center through the surface of the metal base section 23 due to the skin effect, by applying a high-frequency voltage to the metal base section 23 and has a disc shape in which a power supply terminal insertion hole 27 is formed in the vicinity of the center thereof. The dielectric plate 24 can be preferably formed of ceramics having excellent insulation characteristics and thermal conductivity and examples thereof include an aluminum oxide (Al₂O₃) sintered body and an aluminum nitride (AlN) sintered body.

The thickness of the dielectric plate 24 is preferably in the range of 2 mm to 15 mm and more preferably in the range of 4 mm to 8 mm.

When the thickness of the dielectric plate 24 is less than 2 mm, it does not prevent the high-frequency current applied to the metal base section 23 from flowing from the peripheral edge to the center through the surface of the metal base section 23 due to the skin effect. On the other hand, when the thickness of the dielectric plate 24 is greater than 15 mm, the thermal conductivity from the metal base section 23 to the plate-like sample W is decreased, thereby making it difficult to keep the plate-like sample W at a desired constant temperature.

The insulating adhesive bonding layer 36 for adhesively bonding the dielectric plate 24 and the support plate 32 of the electrostatic chuck section 22 to each other is not particularly limited so long as it has excellent insulating characteristics. For example, a material obtained by adding aluminum nitride (AlN) powder or alumina (Al₂O₃) powder as insulating ceramics to a silicon-based adhesive is preferably used.

The reason for using the insulating adhesive bonding layer 36 is as follows. When the dielectric plate 24 and the support plate 32 are adhesively bonded to each other with a conductive adhesive bonding layer interposed therebetween instead of the insulating adhesive bonding layer 36, the current resulting from the high-frequency voltage applied to the metal base section 23 through the conductive adhesive bonding layer flows from the peripheral edge to the central portion through the surface of the metal base section 23 due to the skin effect, thereby not providing the uniform plasma.

Here, the dielectric plate 24 and the concave portion 35 are bonded and fixed to each other with the insulating adhesive bonding layer 36 interposed therebetween. However, the method of fixing the dielectric plate 24 and the concave portion 35 is not particularly limited. For example, they may be bonded and fixed to each other with a conductive adhesive bonding layer interposed therebetween or the adhesive bonding portions of the dielectric plate 24 and the concave portion 35 are made to be complementary to each other and then the dielectric plate 24 and the concave portion 35 may be fitted to each other.

“Method of Manufacturing Electrostatic Chuck Device”

A method of manufacturing an electrostatic chuck device according to this embodiment will be described.

Described here is an example in which the mounting plate 31 and the support plate 32 are formed of the silicon carbide-aluminum oxide complex sintered body substantially containing silicon carbide in the range of 1 wt % to 20 wt %.

Silicon carbide powder having an average particle diameter of 0.1 μm or less is used as the raw powder of silicon carbide (SiC).

The reason is as follows. When the average particle diameter of the silicon carbide (SiC) powder is greater than 0.1 μm, the average particle diameter of the silicon carbide particles in the obtained silicon carbide-aluminum oxide complex sintered body is greater than 0.2 μm and thus the strength of the mounting plate 31 and the support plate 32 is not sufficiently enhanced.

When the mounting plate 31 formed of the silicon carbide-aluminum oxide complex sintered body is exposed to the plasma, the electric field is concentrated on the silicon carbide (SiC) particles to greatly damage the particles, whereby the plasma resistance may be reduced and the electrostatic adsorption force after the plate damage may be reduced.

The powder obtained by a plasma CVD method is preferably used as the silicon carbide (SiC) powder. Specifically, a super fine powder having an average particle diameter of 0.1 μm or less, which is obtained by introducing raw gas of a silane compound or silicon halide and hydrocarbon into plasma in a non-oxidizing atmosphere and carrying out vapor phase reaction while controlling the pressure of the reaction system in the range of 1×10⁵ Pa (1 atm) to 1.33×10 Pa (0.1 Torr), has excellent sintering ability, high purity, and spherical particle shapes and thus is excellent in dispersibility when this is formed.

On the other hand, aluminum oxide (Al₂O₃) powder having an average particle diameter of 1 μm or less is preferably used as the raw powder of aluminum oxide (Al₂O₃).

The reason is as follows. In the silicon carbide-aluminum oxide complex sintered body obtained using the aluminum oxide (Al₂O₃) powder having an average particle diameter larger than 1 μm, the average particle diameter of the aluminum oxide (Al₂O₃) particles in the complex sintered body is greater than 2 μm. Accordingly, the top surface 31a of the mounting plate 31 on which the plate-like sample is mounted can be easily etched by the plasma to form sputtering scars to increase the surface roughness of the top surface 31a, thereby deteriorating the electrostatic adsorption force of the electrostatic chuck device 21.

The aluminum oxide (Al₂O₃) powder is not particularly limited so long as it has an average particle diameter of 1 μm or less and high purity.

Subsequently, the silicon carbide (SiC) powder and the aluminum oxide (Al₂O₃) powder are mixed at a ratio for obtaining a desired volume resistivity value, for example, a composition of 1 to 12 wt % of the silicon carbide (SiC) powder and the balance being the aluminum oxide (Al₂O₃) powder.

Then, the mixed powder is shaped into a predetermined shape by the use of a mold and the resultant shaped body is pressurized and baked, for example, by the use of a hot press (HP) or a hot isotatic press (HIP), thereby obtaining a silicon carbide-aluminum oxide complex sintered body.

For example, the pressurizing force of hot press (HP) conditions is not particularly limited, but is preferably in the range of 5 to 40 MPa when it is intended to obtain the silicon carbide-aluminum oxide complex sintered body. When the pressurizing force is less than 5 MPa, it is not possible to obtain a complex sintered body with a sufficiently high sintering density. On the other hand, when the pressurizing force is greater than 40 MPa, a jig made of graphite or the like is deformed and worn.

The baking temperature is preferably in the range of 1650° C. to 1850° C. When the baking temperature is less than 1650° C., it is not possible to obtain a sufficiently dense silicon carbide-aluminum oxide complex sintered body. On the other hand, when the baking temperature is greater than 1850° C., decomposition or particle growth of components contained in the shaped body may easily occur in the course of baking the sintered body.

The baking atmosphere is preferably an inert gas atmosphere such as argon or nitrogen atmosphere for the purpose of preventing oxidation of silicon carbide.

A power supply terminal insertion hole 37 is mechanically formed at a predetermined position of one sheet of the complex sintered body of two sheets of the resultant silicon carbide-aluminum oxide complex sintered body, which is used as the support plate 32.

As a coating agent for forming the electrostatic-adsorption inner electrode 25, a coating agent is prepared which is made into a paste by adding tantalum carbide (TaC), tantalum nitride (TaN), molybdenum carbide (Mo₂C), molybdenum (Mo), tungsten (W), tantalum (Ta), or the like to the insulating ceramics such as aluminum oxide at a ratio at which the resistance value of the shortest distance L between the points 29a and 29b in the electrode portion 29 is in the range of 10²Ω and 10¹⁰Ω. The coating agent for forming the inner electrode is applied to an area of the support plate 32 in which the electrostatic-adsorption inner electrode is formed, thereby forming an electrode layer.

As a coating agent for forming the insulating layer 33, a coating layer for forming the insulating layer is prepared which is made into paste out of an insulating material containing the same main component as the mounting plate 31 and the support plate 32 and having a resistance value larger than that of the material of the electrostatic-adsorption inner electrode 25. The coating agent for forming the insulating layer is applied to an area other than the area in which the electrostatic-adsorption inner electrode is formed, thereby forming the insulating layer.

Subsequently, the power supply terminal 27 is inserted into the power supply terminal insertion hole 37 of the support plate 32 with a cylindrical insulator 38 interposed therebetween, the surface of the support plate 32 on which the electrode layer and the insulating layer are formed is superposed on the mounting plate 31, the mounting plate 31 and the support plate 32 are heated and pressurized, for example, at a temperature of 1,600° C. or more, the electrostatic-adsorption inner electrode 25 and the insulating layer 33 as a bonding layer are formed of the electrode layer and the insulating layer, respectively, and then the mounting plate 31 and the support plate 32 are bonded to each other with the electrostatic-adsorption inner electrode 25 and the insulating layer 33 interposed therebetween. Then, the top surface 31a of the mounting plate 31 serving as a mounting surface is polished so that Ra (center-line average roughness) is 0.3 μm or less, thereby manufacturing the electrostatic chuck section 22.

On the other hand, the metal base section 23 in which a circular concave portion 35 is formed in the surface thereof and a flow passage 28 for circulating a cooling medium is formed is manufactured using an aluminum (Al) plate. The dielectric plate 24 is manufactured using an aluminum oxide sintered body by shaping and baking aluminum oxide (Al₂O₃) powder.

Subsequently, an insulating adhesive bonding agent is applied to the entire inner surface of the concave portion 35 of the metal base section 23, the dielectric plate 24 is adhesively bonded onto the insulating adhesive bonding agent, an insulating adhesive bonding agent is applied onto the metal base section 23 including the dielectric plate 24, and then the electrostatic chuck section 22 is adhesively bonded onto the insulating adhesive bonding agent.

In the adhesive bonding process, the dielectric plate 24 is bonded and fixed to the concave portion 35 of the metal base section 23 with the insulating adhesive bonding layer 36 interposed therebetween and the support plate 32 of the electrostatic chuck section 22 is bonded and fixed to the metal base section 23 and the dielectric plate 24 with the insulating adhesive bonding layer 36 interposed therebetween.

In this way, the electrostatic chuck device according to this embodiment can be obtained.

As described above, in the electrostatic chuck device according to this embodiment, since the resistance value of the shortest distance L between the point 29a closest to the center axis A of the substrate 26 and the point most distant from the center axis A, that is, the point 29b closest to the peripheral edge of the substrate 26 among distances between two points in the electrode portion 29 of the electrostatic-adsorption inner electrode 25 is set to the range of 10²Ω to 10¹⁰Ω, it is possible to prevent a high-frequency current for generating plasma from flowing from the peripheral portion of the electrostatic chuck section 22 to the central portion through the electrostatic-adsorption inner electrode 25. Accordingly, it is possible to make the plasma density on the surface of the plate-like sample W uniform and thus to perform a uniform plasma process on the entire surface of the plate-like sample W.

By bonding and fixing the dielectric plate 24 to the concave portion 35 of the metal base section 23 with the insulating adhesive bonding layer 36 interposed therebetween and bonding and fixing the dielectric plate 24 to the support plate 32 of the electrostatic chuck section 22 with the insulating adhesive bonding layer 36 interposed therebetween, it is possible to further enhance the insulating characteristic between the metal base section 23 and the electrostatic chuck section 22. Accordingly, when a high-frequency voltage is applied to the metal base section 23, it is possible to prevent a high-frequency current from flowing through the electrostatic-adsorption inner electrode 25 and thus to efficiently accomplish the uniform plasma. Therefore, it is possible to perform a uniform plasma process on the plate-like sample W.

### Second Embodiment

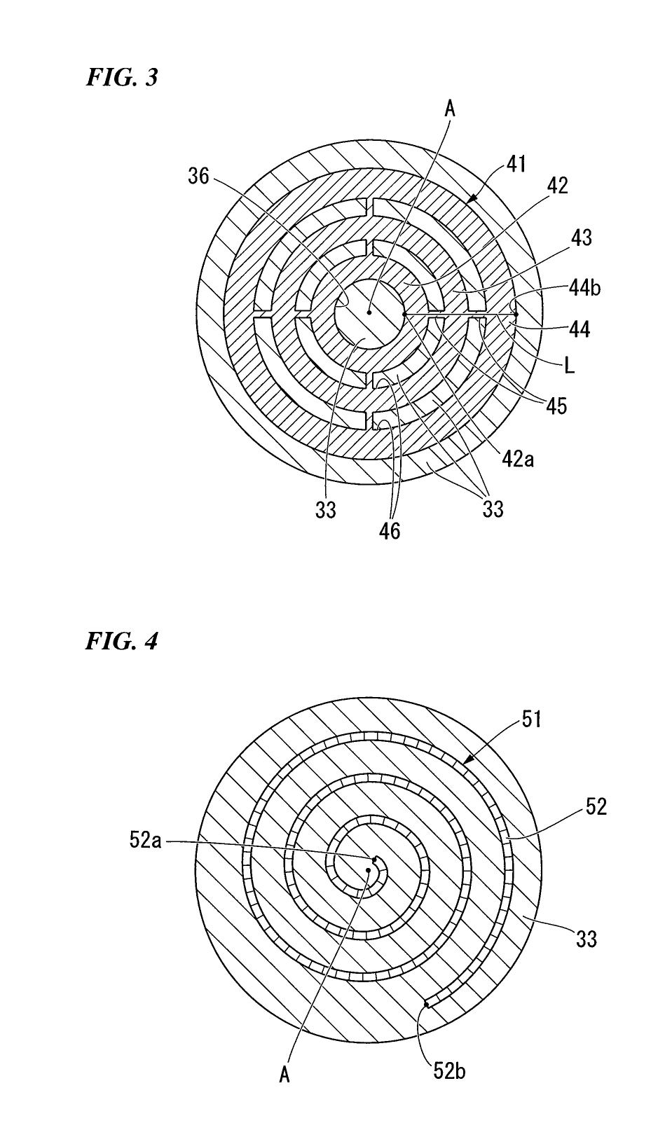

FIG. 3 is a sectional view illustrating a state where an electrostatic-adsorption inner electrode 41 of a unipolar electrostatic chuck device according to a second embodiment of the invention is formed on the support plate 32 of the substrate 26. The electrostatic-adsorption inner electrode 41 according to this embodiment is different from the electrostatic-adsorption inner electrode 25 according to the first embodiment, in that one electrode portion includes three ring-shaped electrodes 42 to 44 arranged concentrically about the center axis A of the substrate and having different diameters and a plurality of conductive connection portions 45 (eight in FIG. 3) electrically connecting the ring-shaped electrodes 42 to 44 to each other.

Among distances between two points in the electrode portion, a resistance value of the shortest distance L between a point 42a closest to the center axis A of the substrate and a point most distant from the center axis A, that is, a point 44b closest to the peripheral edge of the substrate, is set to the range of 10²Ω and 10¹⁰Ω.

In the electrostatic-adsorption inner electrode 41, the connection portion 45 is formed of a material having a resistance value in the range of 10²Ω and 10⁹Ω, the ring-shaped electrodes 42 to 44 are formed of a low-resistance material having a resistance value of 10Ω or less, a resistance value of the shortest distance L between a point 42a closest to the center axis A of the substrate and a point most distant from the center axis A, that is, a point 44b closest to the peripheral edge of the substrate, among distances between two points in the electrode is set to the range of 10²Ω and 10¹⁰Ω.

In the electrostatic-adsorption inner electrode 41 according to this embodiment, it is possible to obtain the same advantages as the electrostatic-adsorption inner electrode 25 according to the first embodiment.

### Third Embodiment

FIG. 4 is a sectional view illustrating a state where an electrostatic-adsorption inner electrode 51 of a unipolar electrostatic chuck device according to a third embodiment of the invention is formed on the support plate 32 of the substrate 26. The electrostatic-adsorption inner electrode 51 is different from the electrostatic-adsorption inner electrode 25 according to the first embodiment, in that one electrode portion includes one spiral electrode 52 extending in a spiral shape from the vicinity of the center axis A of the substrate to the peripheral edge.

Among distances between two points in the spiral electrode 52, a resistance value of a distance in the length direction of the spiral electrode 52 between a point 52a closest to the center axis A of the substrate and a point most distant from the center axis A, that is, a point closest to the peripheral edge of the substrate, is in the range of 102 and 10¹⁰Ω.

In the electrostatic-adsorption inner electrode 51 according to this embodiment, it is possible to obtain the same advantages as the electrostatic-adsorption inner electrode 25 according to the first embodiment.

### Fourth Embodiment

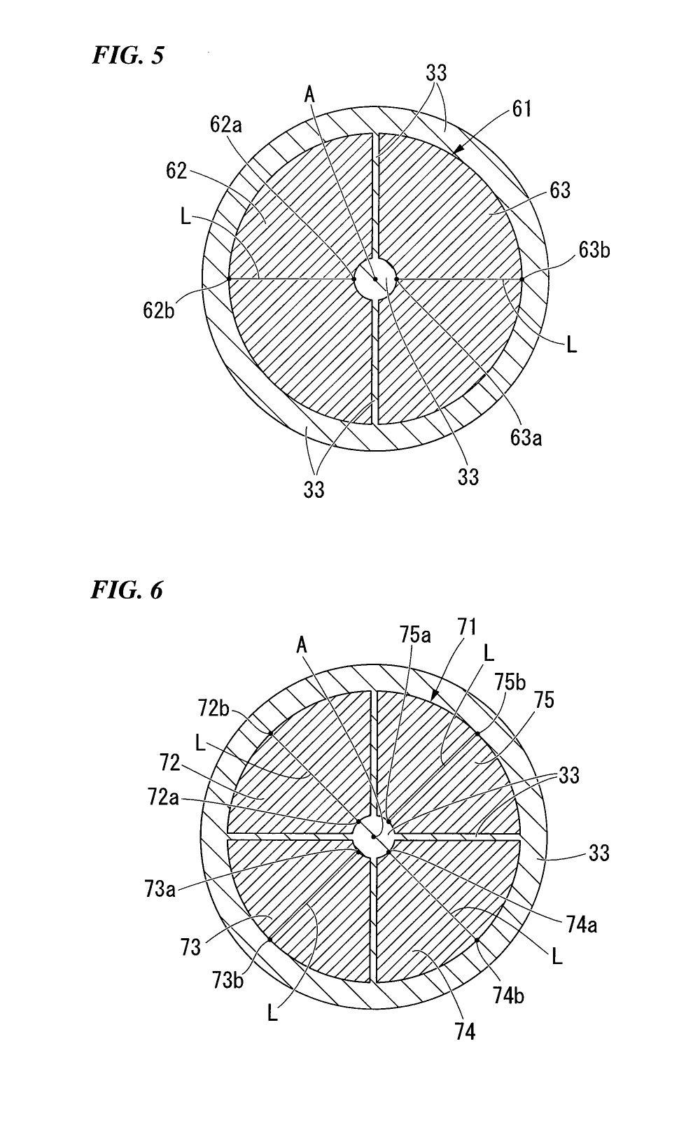

FIG. 5 is a sectional view illustrating a state where an electrostatic-adsorption inner electrode 61 of a bipolar electrostatic chuck device according to a fourth embodiment of the invention is formed on the support plate 32 of the substrate 26. The electrostatic-adsorption inner electrode 61 according to this embodiment is different from the electrostatic-adsorption inner electrode 25 according to the first embodiment, in that two semi-circular electrode portions 62 and 63 are formed by dividing a ring-shaped electrostatic-adsorption inner electrode having a large width into two portions by the use of a straight line passing through the center point, one semi-circular electrode portion 62 is set as a positive electrode, and the other semi-circular electrode portion 63 is set as a negative electrode, thereby making the electrostatic-adsorption inner electrode into a bipolar electrode structure.

Among distances between two points in each of the semi-circular electrode portions 62 and 63, a resistance value of the shortest distance L between a point 62a (63a) closest to the center axis A of the substrate and a point most distant from the center axis A, that is, a point 62b (63b) closest to the peripheral edge of the substrate, is in the range of 10²Ω and 10¹⁰Ω.

In the electrostatic-adsorption inner electrode 61 according to this embodiment, it is possible to obtain the same advantages as the electrostatic-adsorption inner electrode 25 according to the first embodiment.

### Fifth Embodiment

FIG. 6 is a sectional view illustrating a state where an electrostatic-adsorption inner electrode 71 of a bipolar electrostatic chuck device according to a fifth embodiment of the invention is formed on the support plate 32 of the substrate 26. The electrostatic-adsorption inner electrode 71 according to this embodiment is different from the electrostatic-adsorption inner electrode 61 according to the fourth embodiment, in that four quadrant-circular electrode portions 72 to 75 are formed by further dividing the semi-circular electrode portions 62 and 63 of the electrostatic-adsorption inner electrode 61 into two portions, that is, four portions in total, by the use of a straight line passing through the center, one pair of quadrant-circular electrode portions 72 and 74 opposed to each other are set as a positive electrode, and the other pair of quadrant-circular electrode portions 73 and 75 opposed to each other are set as a negative electrode.

Among distances between two points in each of the quadrant-circular electrode portions 72 to 75, a resistance value of the shortest distance L between a point 72a (73a to 75a) closest to the center axis A of the substrate and a point most distant from the center axis A, that is, a point 72b (73b to 75b) closest to the peripheral edge of the substrate, is in the range of 10²Ω and 10¹⁰Ω.

In the electrostatic-adsorption inner electrode 71 according to this embodiment, it is possible to obtain the same advantages as the electrostatic-adsorption inner electrode 61 according to the fourth embodiment.

### Sixth Embodiment

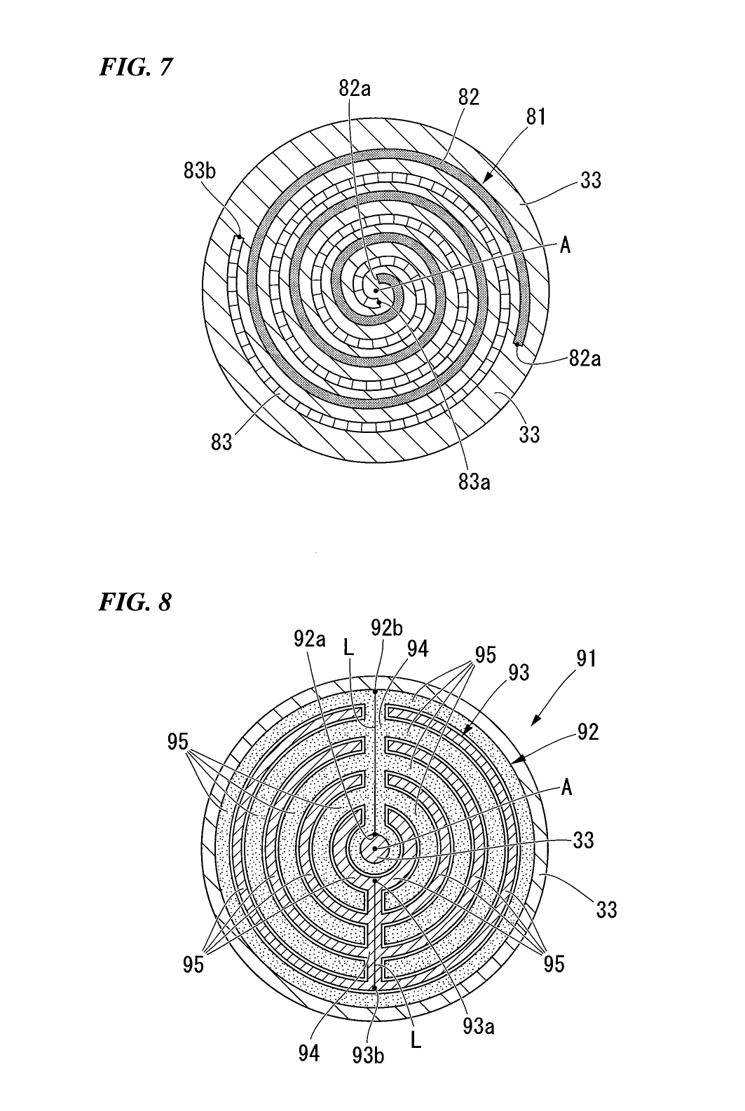

FIG. 7 is a sectional view illustrating a state where an electrostatic-adsorption inner electrode 81 of a bipolar electrostatic chuck device according to a sixth embodiment of the invention is formed on the support plate 32 of the substrate 26. The electrostatic-adsorption inner electrode 81 according to this embodiment is different from the electrostatic-adsorption inner electrode 51 according to the third embodiment, in that a pair of electrode portions includes two spiral electrodes 82 and 83 extending from the vicinity of the center axis A of the substrate toward the peripheral edge and being combined to be fitted to each other, one spiral electrode 82 is set as a positive electrode, and the other spiral electrode 83 is set as a negative electrode, thereby making the electrostatic-adsorption inner electrode 51 into a bipolar electrode structure.

Among distances between two points in each of the spiral electrodes 82 and 83, a resistance value of a distance in the length direction of the spiral electrode 82 (83) between a point 82a (83a) closest to the center axis A of the substrate and a point most distant from the center axis A, that is, a point 82b (83b) closest to the peripheral edge of the substrate, is in the range of 10²Ω and 10¹⁰Ω.

In the electrostatic-adsorption inner electrode 81 according to this embodiment, it is possible to obtain the same advantages as the electrostatic-adsorption inner electrode 25 according to the first embodiment.

### Seventh Embodiment

FIG. 8 is a sectional view illustrating a state where an electrostatic-adsorption inner electrode 91 of a bipolar electrostatic chuck device according to a seventh embodiment of the invention is formed on the support plate 32 of the substrate 26. The electrostatic-adsorption inner electrode 91 according to this embodiment is different from the electrostatic-adsorption inner electrode 61 according to the fourth embodiment, in that a pair of electrode portions 92 and 93 each are formed in such a configuration that a plurality of circular branch portions 95 are disposed on both sides of a band-shaped base portion 94 and the branch portions 95 are fitted to each other, one electrode portion 92 is set as a positive electrode, and the other electrode portion 93 is set as a negative electrode.

Among distances between two points in each of the electrode portions 92 and 93, a resistance value of the shortest distance L between a point 92a (93a) closest to the center axis A of the substrate and a point most distant from the center axis A, that is, a point 92b (93b) closest to the peripheral edge of the substrate, is in the range of 10²Ω and 10¹⁰Ω.

In the electrostatic-adsorption inner electrode 91, the resistance value of the band-shaped base portion 94 corresponding to the connection portion of the circular-arc branch portions 95 is set to the range of 10²Ω and 10¹⁰Ω and the circular-arc branch portions 95 are made of, for example, a low-resistance material having a resistance of 10²Ω or less.

In the electrostatic-adsorption inner electrode 91 according to this embodiment, it is possible to obtain the same advantages as the electrostatic-adsorption inner electrode 61 according to the fourth embodiment.

### Eighth Embodiment

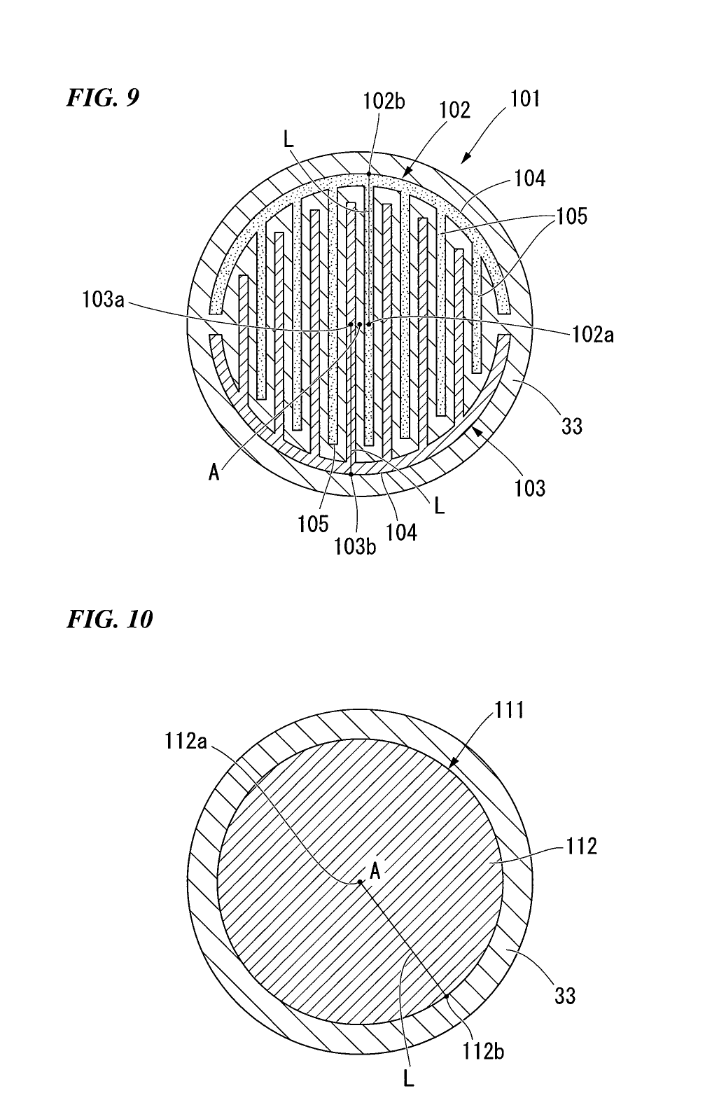

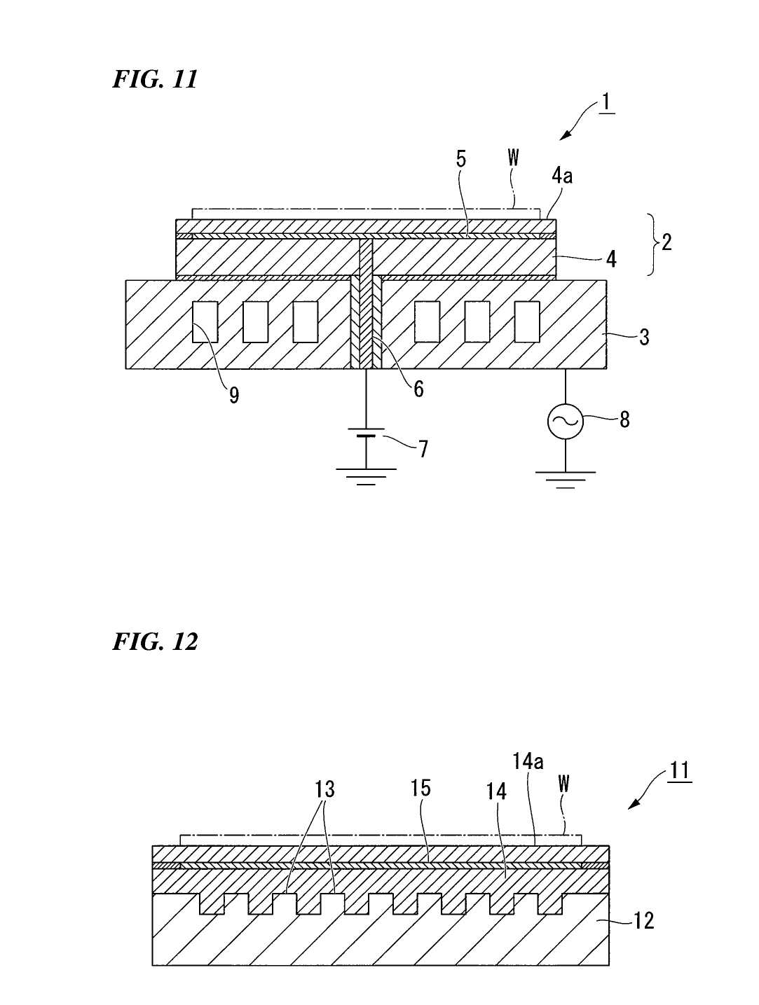

FIG. 9 is a sectional view illustrating a state where an electrostatic-adsorption inner electrode 101 of a bipolar electrostatic chuck device according to an eighth embodiment of the invention is formed on the support plate 32 of the substrate 26. The electrostatic-adsorption inner electrode 101 according to this embodiment is different from the electrostatic-adsorption inner electrode 91 according to the seventh embodiment, in that a pair of electrode portions include comb-shaped electrode portions 102 and 103, each of the comb-shaped electrode portions 102 and 103 has a configuration such that a plurality of band-shaped branch portions 105 parallel to each other are disposed in a circular-arc base portion 104, the branch portions 105 of the electrode portions 102 and 103 are alternately arranged toward each other, one electrode portion 102 is set as a positive electrode, and the other electrode portion 103 is set as a negative electrode.

Among distances between two points in each of the comb-shaped electrode portions 102 and 103, a resistance value of the shortest distance L between a point 102a (103a) closest to the center axis A of the substrate and a point most distant from the center axis A, that is, a point 102b (103b) closest to the peripheral edge of the substrate, is in the range of 10²Ω and 10¹⁰Ω.

In the electrostatic-adsorption inner electrode 101 according to this embodiment, it is possible to obtain the same advantages as the electrostatic-adsorption inner electrode 91 according to the seventh embodiment.

### Ninth Embodiment

FIG. 10 is a sectional view illustrating a state where an electrostatic-adsorption inner electrode 111 of a unipolar electrostatic chuck device according to a ninth embodiment of the invention is formed on the support plate 32 of the substrate 26. The electrostatic-adsorption inner electrode 111 according to this embodiment is different from the electrostatic-adsorption inner electrode 25 according to the first embodiment, in that the inner electrode includes a disc-shaped electrode 112 disposed about the center axis A of the substrate.

The resistance value of the shortest distance L between a point 112a corresponding to the center axis A of the substrate and a point most distant from the center axis A, that is, a point 112b closest to the peripheral portion of the substrate, among distances between two points in the disc-shaped electrode 112 is in the range of 10²Ω and 10¹⁰Ω.

In the electrostatic-adsorption inner electrode 111 according to this embodiment, it is possible to obtain the same advantages as the electrostatic-adsorption inner electrode 25 according to the first embodiment.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An electrostatic chuck device comprising:
an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and
a metal base section that is fixed to the other main surface of the electrostatic chuck section so as to be incorporated into a body and that serves as a high frequency generating electrode,
wherein the electrostatic-adsorption inner electrode has one or more electrode portions, and
wherein a resistance value of a distance between a point corresponding to a center axis of the substrate or a point closest to the center axis and a point most distant from the center axis among distances between two points in the electrode portion is in the range of 10²Ω to 10¹⁰Ω.
